(19) United States
(12) Patent Application Publication
(10) Pub. No.: US 2005/0173799 A1
(43) Pub. Date: Aug. 11, 2005

(54) Interconnect structure and method for its fabricating

(75) Inventors: Juan-Jann Jou, Tainan County (TW); Yu-Hua Lee, Hsinchu County (TW); Chin-Tien Yang, Kaohsiung County (TW); Chia-Hung Lai, Taichung City (TW); Connie Hsu, Yunlin County (TW); Mu-Yi Lin, Taichung City (TW); Min Cao, Hsin-Chu (TW); Chia-Yu Ku, Taipei County (TW); Yuh-Da Fan, Shin Chu City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co., Ltd., Hsin-Chu (TW)

(21) Appl. No.: 10/772,736

(22) Filed: Feb. 5, 2004

(51) Int. Cl. H01L 21/4763; H01L 23/48; H01L 29/40; H01L 21/31

(52) U.S. Cl. 257/751; 438/622; 438/643; 438/758

(57) ABSTRACT

A method of fabricating an interconnect structure, including providing a semiconductor substrate having a first conductive layer thereon, and forming a dielectric layer overlying the semiconductor substrate and the first conductive layer. An opening is formed in the dielectric layer extending to the first conductive layer. A portion of the first conductive layer is removed through the opening to form a recess having a substantially curvilinear profile. The opening and the recess are filled with a second conductive layer.

### BACKGROUND

The present invention relates generally to semiconductor fabrication and, more particularly, to fabrication of interconnects having substantially curvilinear interconnect interfaces.

Integrated circuits are manufactured by fabricating electronic devices in a semiconductor substrate. Multi-level interconnections are formed to connect the devices to create desired circuits.

Aluminum and aluminum alloys are the most widely used interconnection metallurgies for integrated circuits. However, in response to the scaling of feature sizes to submicron and deep-submicron technology nodes, copper is also employed as an interconnection metal due to its low electric resistivity and its high resistance to electromigration (EM) and stress voiding.

However, copper implementation can suffer from high diffusivity in common insulating materials such as silicon oxide and oxygen-containing polymers. The diffusion can cause corrosion of the copper, which can result in loss of adhesion, delamination, void formation, and electric failure of the parent circuitry. A copper diffusion barrier is therefore employed for most copper interconnects. For example, a diffusion barrier is formed between copper components and inter-layer dielectrics, other insulators, and silicon substrates.

Damascene processing is often employed to form such copper conductors and copper diffusion barriers. However, during damascene processing, copper residue and other residue materials can adhere to the openings in which interconnects and other copper components are to be formed. The residue materials can contaminate the dielectric layer and reduce the reliability of the interconnects. The residue materials can also be detrimental to the quality of interfaces between conductive lines and plugs, thereby decreasing device reliability.

Accordingly, what is needed is an interconnect structure and method of manufacturing thereof that addresses the above-discussed issues.

### BRIEF DESCRIPTION OF THE DRAWINGS

The present disclosure is best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a flow chart of one embodiment of a method of fabricating an interconnect according to aspects of the present disclosure.

FIGS. 2-4, 5A-5D, 6A-6D, and 7A-7D illustrate sectional views of interconnect structures during various stages of fabrication in one embodiment according to aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

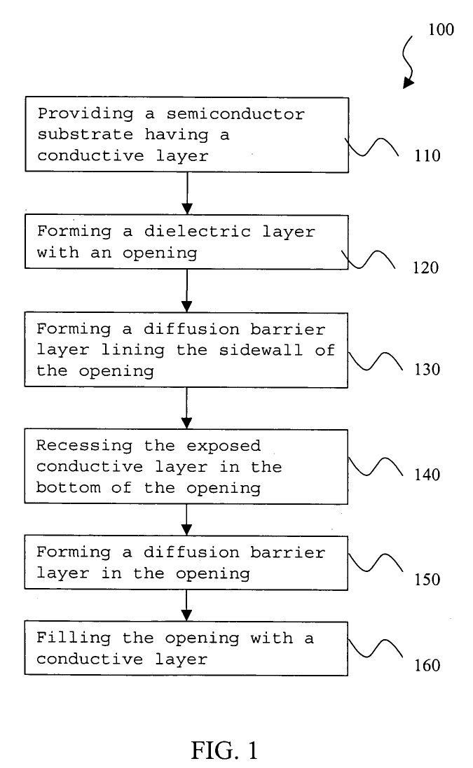

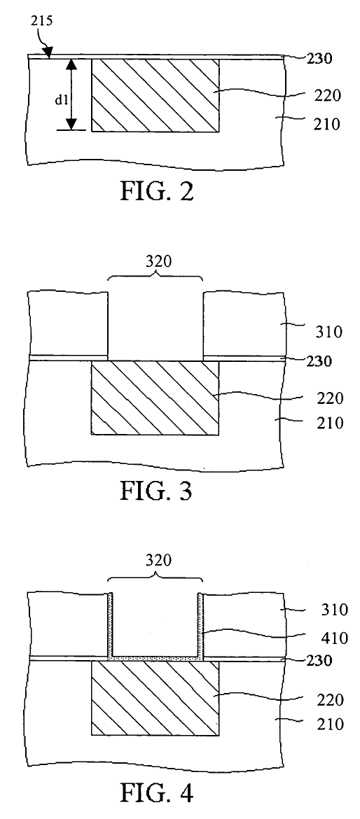

Referring to FIG. 1, illustrated is a flow chart of one embodiment of a method 100 of fabricating an interconnect according to aspects of the present disclosure. The method 100 shown in FIG. 1 will be described herein concurrently with additional reference to FIGS. 2-4, 5A-5D, 6A-6D, and 7A-7D. That is, FIGS. 2-4, 5A-5D, 6A-6D, and 7A-7D illustrate sectional views of embodiments of interconnect structures during various stages of fabrication which, in some embodiments, are in accord with aspects of the method 100 shown in FIG. 1.

Thus, referring to FIGS. 1 and 2 collectively, the method 100 includes a step 110, which includes providing a substrate 210 having a conductive layer 220 formed at least partially therein. The conductive layer 220 may be deposited in a recess formed in the substrate 210 by chemical vapor deposition (CVD) including plasma-enhanced CVD (PECVD), physical vapor deposition (PVD) including ionized PVD (I-PVD), atomic layer deposition (ALD), plating, and/or other processes. Chemical-mechanical planarization and/or chemical-mechanical polishing (collectively referred to herein as CMP) may also be employed during formation of the conductive layer 220. For example, CMP may be employed to planarized the conductive layer 220 such that it is substantially coplanar with a surface 215 of the substrate 210, as shown in FIG. 2. In another embodiment, planarization of the conductive layer 220 may be less extensive, such that the conductive layer 220 may at least partially extend from the substrate 210 above the surface 215. Characterizations herein of the conductive layer 220 as being formed in the substrate 210 is intended to capture both of these embodiments, among others.

The substrate 210 may comprise an elementary semiconductor such as crystal silicon, polycrystalline silicon, amorphous silicon, and/or germanium. The substrate 210 may also or alternatively comprise a compound semiconductor such as silicon carbide and/or gallium arsenic. The substrate 210 may also or alternatively comprise an alloy semiconductor such as SiGe, GaAsP, AlInAs, AlGaAs, and/or GaInP, or any combination and/or alloy thereof. Furthermore, the substrate 210 may be or comprise a bulk semiconductor such as bulk silicon, and such a bulk semiconductor may include an epi silicon layer. The substrate 210 may also be or comprise a semiconductor-on-insulator substrate, such as a silicon-on-insulator (SOI) substrate, or a thin-film transistor (TFT) substrate. The substrate 210 may also comprise a multiple silicon structure or a multilayer compound semiconductor structure.

The conductive layer 220 may be or comprise aluminum, an aluminum alloy, copper, a copper alloy, tungsten, combinations and/or alloys thereof, and/or other conductive materials. The conductive layer 220 may be a conductive feature connecting semiconductor devices, integrated circuit devices and/or components, and/or interconnects therein. The depth d1 of the conductive layer 220 may range between about 1500 Å and about 5000 Å. For example, in one embodiment, the depth d1 is about 3500 Å.

The substrate 210 provided in step 110 may include a dielectric layer 230 overlying the semiconductor substrate 210 and the conductive layer 220. The dielectric layer 230 may be an etch stop layer and/or a diffusion barrier layer, and may comprise one or more individual layers. The dielectric layer 230 may be or comprise silicon nitride and/or other dielectric and/or etch stop materials.

Referring to FIGS. 1 and 3 collectively, the method 100 also includes a step 120, in which a dielectric layer 310 is deposited on the surface of the substrate 210 or, as in the illustrated embodiment, on the dielectric layer 230. The dielectric layer 310 may be an inter-metal dielectric (IMD). The dielectric layer 310 may comprise silicon dioxide, polyimide, spin-on-glass (SOG), fluoride-doped silicate glass (FSG), Black Diamond® (a product of Applied Materials of Santa Clara, Calif.), Xerogel, Aerogel, amorphous fluorinated carbon, and/or other materials, and may be formed by CVD, PECVD, ALD, PVD, spin-on coating and/or other processes. In one embodiment, the dielectric layer 310 may be or comprise a low-k material having a dielectric constant k of less than or equal to about 3.2 (or less than about 3.3). For example, the dielectric layer may comprise organic low-k material, CVD low-k material, and/or a combination thereof.

As shown in FIG. 3, the dielectric layer 310 is patterned by photolithography, etching, and/or other means to form an opening 320 therein, thereby exposing a portion of the underlying dielectric layer 230 or conductive layer 220. The opening 320 may be a via hole or a dual damascene opening (e.g., an opening comprising a via hole and a conductive line trench).

If necessary or desired, the exposed portion of the dielectric layer 230 proximate the opening 320 may also be removed, such as by dry etching and/or other processes, to expose a portion of the underlying conductive layer 220. Removal of the dielectric layer 230 may employ a chemistry comprising CH₄ as a primary gas, possibly mixed with O₂ and N₂ to adjust the etching rate and selectivity.

Referring to FIGS. 1 and 4 collectively, the method 100 may also include a step 130, in which a diffusion barrier layer 410 is deposited, such as by self-ionized plasma (SIP) PVD and/or ionized metal plasma (IMP) PVD, wherein the diffusion barrier layer 410 at least partially lines the opening 320. The diffusion barrier layer 410 may be or comprise Ta, TaN, Ti, TiN, combinations and/or alloys thereof, and/or other barrier materials.

In one embodiment, the barrier layer 410 may be formed prior to removing a portion of the dielectric layer 230. In such an embodiment, a bottom portion of the barrier layer 410 and a portion of the dielectric layer 230 may be sequentially removed, such as by dry etching and/or sputtering.

The bottom portion of the barrier layer 410 proximate the conductive layer 220, whether formed prior to or after removing a portion of the dielectric layer 230, may be removed by in-situ sputtering utilizing SIP or IMP. Consequently, at least a portion of the conductive layer 220 may be exposed.

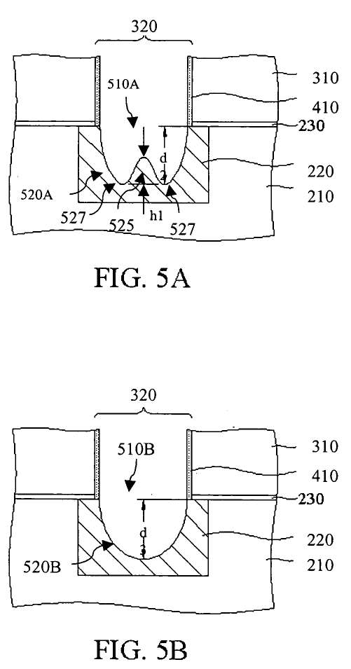

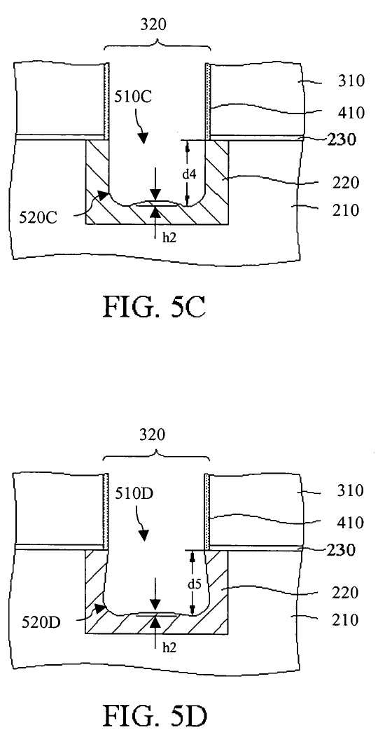

Referring to FIGS. 1 and 5A-D collectively, the method 100 also includes a step 140, in which a recess is formed in the conductive layer 220. Four embodiments of recesses 510A, 510B, 510C, and 510D are shown in FIGS. 5A to 5D, respectively. For the sake of clarity, the recesses 510A, 510B, 510C, and 510D may be collectively referred to herein as a recess 510. The recess 510 may have a depth of at least about 200 Å. For example, the recess 510 may have a depth ranging between about 300 Å and about 800 Å. In one embodiment, the recess 510 has a depth ranging between about 500 Å and about 700 Å.

The recess 510 may be formed by etching the conductive layer 220, possibly by in-situ sputtering utilizing SIP or IMP. For example, commercial SIP PVD systems or IMP PVD systems provide cleaning models of controllable argon ion (Ar+) sputtering mechanism to recess the exposed conductive layer 220 to a predetermined thickness.

As shown in FIG. 5A, the recess 510A may have a curvilinear, substantially W-shaped or other undulating profile 520A. For example, in the embodiment shown in FIG. 5A, the W-shaped profile 520A includes one peak 525 and two valleys 527, although other numbers of peaks 525 and valleys 527 are within the scope of the present disclosure. The height h1 of the peak 525 may range between about 25% and about 75% of the depth d2 of the recess 510A. For example, in the embodiment shown in FIG. 5A, the height h1 is about 50% of the depth d2. The depth d2 of the profile 520A may range between about 300 Å and about 800 Å. In one embodiment, the depth d2 ranges between about 500 Å and about 700 Å. The radii of the peaks and valleys 525, 527 may range between about 5% and about 50% of the depth d2, although other radii are also within the scope of the present disclosure.

In one embodiment, the profile 520A is formed by etching the conductive layer 220 utilizing SIP, possibly employing an SIP-PVD system, such as the INOVA HCM provided by Novellus Systems, Inc., of San Jose, Calif. The SIP-PVD system may also be employed to deposit diffusion barrier layers and/or seed layers, such as in embodiments in which the recess 510A is or comprises a high-aspect via opening, as described below. An SIP-PVD system may generate Ar ions which reach and bombard the conductive layer 220. The Ar ions are directed by adjusting a bias of the SIP system to initially bombard the sidewalls of the opening 320 and then be refracted to bombard the conductive layer 220, thereby resulting in the profile 520A.

Similarly, the bias of the SIP-PVD system can be adjusted to direct Ar ions bombarding the conductive layer 220 to form an opening 510B with a substantially curvilinear, concave profile 520B as shown in FIG. 5B, an opening 510C with a shallow-peaked curvilinear profile 520C as shown in FIG. 5C, or an opening 510D with a trapezoidal, shallow-peaked, curvilinear profile 520D as shown in FIG. 5D. The heights h2 of the peaks 540 in the shallow-peaked profiles 520C and 520D may range between about 5% and about 25% of the corresponding depths d3, d4. For example, in the embodiments shown in FIG. 5C and 5D, the height h2 is about 5% of the corresponding depths d3, d4.

The depths d3, d4, d5 of each of these profiles may be at least 200 Å, and may range between about 300 Å and about 800 Å. In one embodiment, the depths d3, d4, d5 range between about 500 Å and about 700 Å. The profiles 520A, 520B, 520C, 520D of the recessed conductive layer 220 are determined by the incident angle of Ar ions, which may be tuned according to the SIP bias or magnetic field adjustment and the aspect ratio of the opening 320. The incident angle may also affect the parallelism of the sidewalls of the profile, such that the sidewalls may be substantially parallel or, as with the trapezoidal profile 520D, such that the sidewalls are not substantially parallel. For example, the sidewalls of the trapezoidal profile 520D may be angularly offset by an angle ranging up to about 30°.

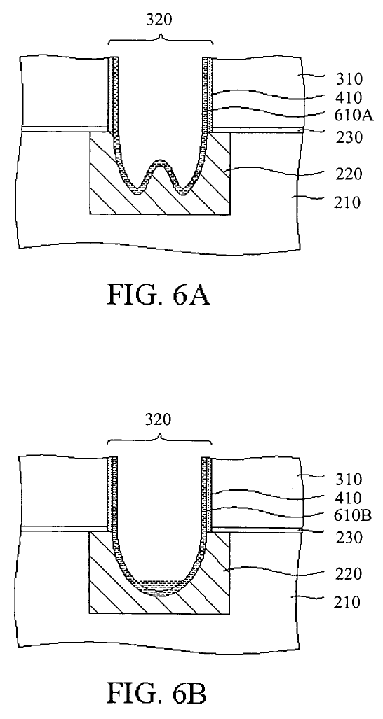

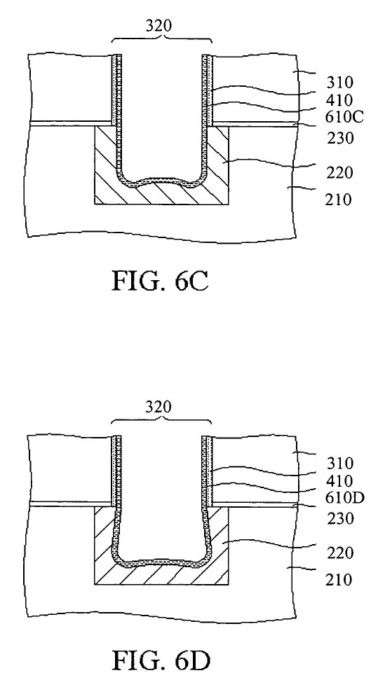

Referring to FIGS. 1 and 6A-6D collectively, the method 100 may also include a step 150, in which a diffusion barrier layer may be optionally deposited as a conformal layer lining the bottom and/or sidewalls of the recess 510. For example, in the embodiments shown in FIGS. 6A-6D, respectively, diffusion barrier layers 610A-610D are formed in-situ by an IMP or SIP system, such that the diffusion barrier layers 610A-610D line the openings 510A-510D, respectively. The diffusion barrier layers 610A-610D may be substantially similar to the barrier layer 410 described above. For example, the diffusion barrier layers 610A-610D may be or comprise Ta, TaN, Ti, TiN, a combination and/or alloy thereof, and/or other barrier materials.

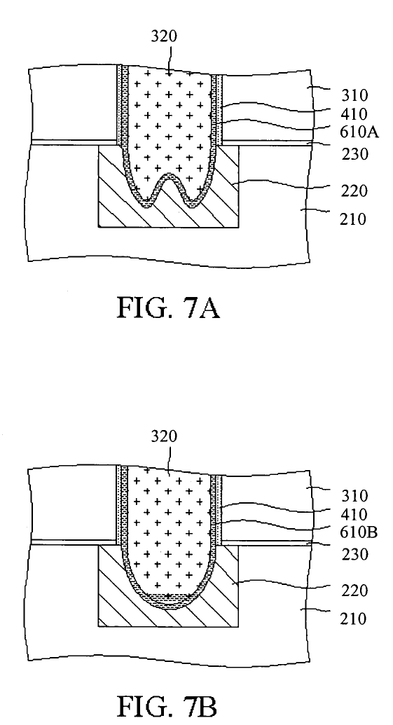

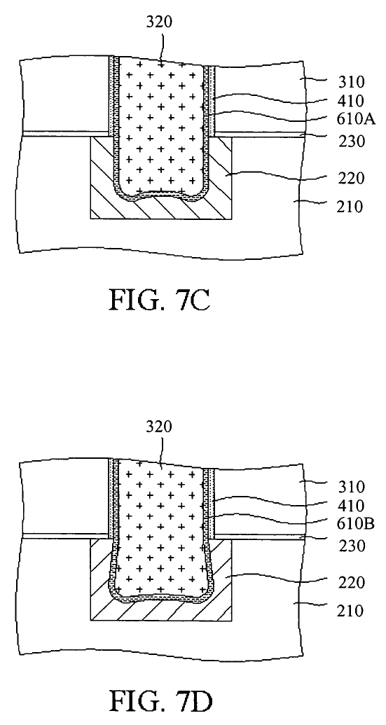

Referring to FIGS. 1 and 7A-7D respectively, the method 100 also includes a step 160, in which the openings 510A-510D are each filled with a conductive plug 710A-710D, respectively, such as by damascene processing. In one embodiment, one or more seed layers comprising copper, copper alloys, and/or other seed materials are deposited on the diffusion barrier layers 610A-610D, thereby lining the openings 510A-510D, respectively, such as by PVD, IMP, SIP, and/or other processes. The openings 510A-510D may then be filled with a conductive material which, in one embodiment, may be substantially similar to the composition of the conductive layer 220. The conductive plugs 710A-710D may be or comprise aluminum, an aluminum alloy, copper, a copper alloy, tungsten, a combination and/or alloy thereof, and/or other conductive materials. The conductive material employed to form the conductive plugs 710A-710D may be formed in the openings 510A-510D by electroplating and/or other deposition processes. Excess conductive material formed the dielectric layer 310 may then removed by CMP and/or other methods to form the conductive plugs 710A-710D in the openings 510A-510D, respectively.

The contact interface between the conductive layer 220 and the conductive plugs 710A-710D is increased by the recess 510 in the conductive layer 220. The contact area of the interface may further be modified by tuning the incident angle of Ar ions. Moreover, the conductive material proximate the bottom of the conductive layer 220 which may become damaged during etching operations may be removed during the formation of the recess 510 and subsequently filled with newly grown or otherwise deposited conductive material. Thus, stress migration (SM) and electromigration (EM) resistance of interconnects formed thereof may be improved.

Thus, the present disclosure provides a method of fabricating an interconnect structure, including providing a semiconductor substrate having a first conductive layer thereon, and forming a dielectric layer overlying the semiconductor substrate and the first conductive layer. An opening is formed in the dielectric layer extending to the first conductive layer. A portion of the first conductive layer is removed through the opening to form a recess having a substantially curvilinear profile. The opening and the recess are filled with a second conductive layer. In one embodiment, the method includes forming a diffusion barrier layer at least partially lining the opening by employing one of a self-ionized plasma (SIP) system and an ionized metal plasma (IMP) system. Moreover, the conductive layer may be recessed by in-situ recessing employing one of the SIP system and the IMP system.

The present disclosure also provides an interconnect structure including, in one embodiment, a first conductive layer located in a substrate, and a dielectric layer overlying the first conductive layer and having an opening extending to the first conductive layer. A second conductive layer is located in the opening and contacts a portion of the first conductive layer, wherein an interface between the first and second conductive layers substantially conforms to a substantially curvilinear profile.

An integrated circuit device is also introduced in the present disclosure. In one embodiment, the integrated circuit device includes a plurality of semiconductor devices coupled to a substrate, and an interconnect structure coupling ones of the plurality of semiconductor devices. The interconnect structure includes a plurality of first conductive layers and a dielectric layer overlying ones of the plurality of first conductive layers and having a plurality of openings each extending to one of the plurality of first conductive layers. The interconnect structure also includes a plurality of second conductive layers located in ones of the plurality of openings and each contacting a portion of one of the plurality of first conductive layers, wherein each interface between corresponding ones of the first and second conductive layers substantially conforms to a substantially curvilinear profile.

Although embodiments of the present disclosure have been described in detail, those skilled in the art should understand that they can make various changes, substitutions and alterations herein without departing from the spirit and scope of the present disclosure.

1. A method of fabricating an interconnect structure, comprising:
providing a semiconductor substrate having a first conductive layer thereon;
forming a dielectric layer overlying the semiconductor substrate and the first conductive layer;
forming an opening in the dielectric layer extending to the first conductive layer;
removing a portion of the first conductive layer through the opening to form a recess having a substantially curvilinear profile; and
filling the opening and the recess with a second conductive layer.

2. The method of claim 1 wherein the recess has a depth of at least 200 Å.

3. The method of claim 1 wherein the recess has a depth ranging between about 300 Å and about 800 Å.

4. The method of claim 1 wherein the recess has a depth ranging between about 500 Å and about 700 Å.

5. The method of claim 1 wherein removing a portion of the first conductive layer comprises sputtering.

6. The method of claim 1 wherein removing a portion of the first conductive layer comprises sputtering employing a self-ionized plasma (SIP) system.

7. The method of claim 1 wherein removing a portion of the first conductive layer comprises sputtering employing an ionized metal plasma (IMP) system.

8. The method of claim 1 further comprising forming a diffusion barrier layer lining the sidewalls of the opening prior to removing a portion of the first conductive layer.

9. The method of claim 1 further comprising forming a diffusion barrier layer conformal to the profile of the recess before filling the opening and the recess.

10. The method of claim 1 wherein the recess profile is substantially W-shaped.

11. The method of claim 1 wherein the recess profile includes a peak having a height ranging between about 25% and about 75% of a depth of the recess.

12. The method of claim 1 wherein the recess profile includes a peak having a height that is about 50% of a depth of the recess.

13. The method of claim 1 wherein the recess profile is substantially concave.

14. The method of claim 1 wherein the recess profile is a shallow-peaked profile including a peak having a height ranging between about 5% and about 25% of a depth of the recess.

15. The method of claim 1 wherein the recess profile is a substantially trapezoidal, peaked profile.

16. A method of fabricating an interconnect structure, comprising:
providing a semiconductor substrate having a first conductive layer thereon;
forming a dielectric layer overlying the semiconductor substrate and the first conductive layer;
forming an opening in the dielectric layer exposing the first conductive layer;
forming a diffusion barrier layer at least partially lining the opening by employing one of a self-ionized plasma (SIP) system and an ionized metal plasma (IMP) system;
removing a portion of the first conductive layer in-situ through the opening to form a recess having a substantially curvilinear profile in the first conductive layer by employing one of the SIP system and the IMP system; and
filling the opening and the recess with a second conductive layer.

17. The method of claim 16 wherein the recess has a depth of at least 200 Å.

18. The method of claim 16 wherein the recess has a depth ranging between about 300 Å and about 800 Å.

19. The method of claim 16 wherein the recess has a depth ranging between about 500 Å and about 700 Å.

20. The method of claim 16 further comprising forming a diffusion barrier layer substantially conformal to the profile of the recess before filling the opening and the recess.

21. The method of claim 16 wherein the recess profile is substantially W-shaped.

22. The method of claim 16 wherein the recess profile includes a peak having a height ranging between about 25% and about 75% of a depth of the recess.

23. The method of claim 16 wherein the recess profile includes a peak having a height that is about 50% of a depth of the recess.

24. The method of claim 16 wherein the recess profile is substantially concave.

25. The method of claim 16 wherein the recess profile is a shallow-peaked profile including a peak having a height ranging between about 5% and about 25% of a depth of the recess.

26. The method of claim 16 wherein the recess profile is a substantially trapezoidal, peaked profile.

27. An interconnect structure, comprising:
a first conductive layer located in a substrate;
a dielectric layer overlying the first conductive layer and having an opening extending to the first conductive layer; and
a second conductive layer located in the opening and contacting a portion of the first conductive layer, wherein an interface between the first and second conductive layers substantially conforms to a substantially curvilinear profile.

28. The interconnect structure of claim 27 wherein the profile has a depth relative to the substrate of at least 200 Å.

29. The interconnect structure of claim 27 wherein the profile has a depth relative to the substrate ranging between about 300 Å and about 800 Å.

30. The interconnect structure of claim 27 wherein the profile has a depth relative to the substrate ranging between about 500 Å and about 700 Å.

31. The interconnect structure of claim 27 further comprising a diffusion barrier layer interposing the dielectric layer and the second conductive layer.

32. The interconnect structure of claim 27 further comprising a diffusion barrier layer interposing the first and second conductive layers and substantially conforming to the interface profile.

33. The interconnect structure of claim 27 wherein the interface profile is substantially W-shaped.

34. The interconnect structure of claim 27 wherein the interface profile includes a peak having a height ranging between about 25% and about 75% of a depth of the interface profile relative to the substrate.

35. The interconnect structure of claim 27 wherein the interface profile includes a peak having a height that is about 50% of a depth of the interface profile relative to the substrate.

36. The interconnect structure of claim 27 wherein the interface profile is substantially concave relative to the substrate.

37. The interconnect structure of claim 27 wherein the interface profile is a shallow-peaked profile including a peak having a height ranging between about 5% and about 25% of a depth of the interface profile relative to the substrate.

38. The interconnect structure of claim 27 wherein the interface profile is a substantially trapezoidal, peaked profile.

39. The interconnect structure of claim 27 wherein the opening is one of a via hole opening and a dual damascene opening.

40. The interconnect structure of claim 27 wherein at least one of the first and second conductive layers comprises one of copper and a copper alloy.

41. An integrated circuit device, comprising:
a plurality of semiconductor devices coupled to a substrate; and
an interconnect structure coupling ones of the plurality of semiconductor devices, the interconnect structure including:
a plurality of first conductive layers;
a dielectric layer overlying ones of the plurality of first conductive layers and having a plurality of openings each extending to one of the plurality of first conductive layers; and
a plurality of second conductive layers located in ones of the plurality of openings and each contacting a portion of one of the plurality of first conductive layers, wherein each interface between corresponding ones of the first and second conductive layers substantially conforms to a substantially curvilinear profile.

42. The integrated circuit device of claim 41 wherein the profile has a depth relative to a corresponding one of the plurality of first conductors of at least 200 Å.

43. The integrated circuit device of claim 41 wherein the profile has a depth relative to a corresponding one of the plurality of first conductors ranging between about 300 Å and about 800 Å.

44. The integrated circuit device of claim 41 wherein the profile has a depth relative to a corresponding one of the plurality of first conductors ranging between about 500 Å and about 700 Å.

45. The integrated circuit device of claim 41 wherein the interconnect structure further includes a plurality of diffusion barrier layers each interposing the dielectric layer and one of the plurality of second conductive layers.

46. The integrated circuit device of claim 41 wherein the interconnect structure further includes a plurality of diffusion barrier layers each interposing one of the plurality of first conductive layers and a corresponding one of the plurality of second conductive layers.

47. The integrated circuit device of claim 41 wherein the profile is substantially W-shaped.

48. The integrated circuit device of claim 41 wherein the profile includes a peak having a height ranging between about 25% and about 75% of a depth of the profile relative to a corresponding one of the plurality of first conductive layers.

49. The integrated circuit device of claim 41 wherein the profile is substantially concave relative to a corresponding one of the plurality of first conductive layers.

50. The integrated circuit device of claim 41 wherein the profile is a shallow-peaked profile including a peak having a height ranging between about 5% and about 25% of a depth of the profile relative to a corresponding one of the plurality of first conductive layers.

51. The integrated circuit device of claim 41 wherein the profile is a substantially trapezoidal, peaked profile.
